(19) United States
(12) Patent Application Publication
(10) Pub. No.: US 2004/0094695 A1
(43) Pub. Date: May 20, 2004

(54) Digital CMOS sensor

(76) Inventor: Wen Ching Chen, Taichung (TW)

Correspondence Address: WEN CHING CHEN, P.O. BOX 2103, Taichung, TW

(21) Appl. No.: 10/298,281

(22) Filed: Nov. 18, 2002

(51) Int. Cl. H01J 3/14; H01L 27/00

(52) U.S. Cl. 250/216; 250/208.1

(57) ABSTRACT

A digital CMOS sensor includes a chip adapted to be electrically connected to a printed circuit board by multiple conducting wires. A transparent layer is fully enveloped the chip and the multiple wires. A convex lens is disposed on a top face of the transparent layer and aligns with the chip for guiding light rays penetrating the transparent layer to the chip.

### BACKGROUND OF THE INVENTION

1. Field of the Invention

The present invention relates to a sensor, and more particularly to a digital CMOS sensor.

2. Description of Related Art

A digital image technique has been wildly applied to image shooting instrument such as digital camera, image scanner, etc. FIG. 6 shows the digital image lens combination of he digital camera. A conventional CMOS sensor (61) is disposed on a circuit board (6). The CMOS sensor (61) has a chip (62) secured therein. The lens seat (7) has a focusing lens (71) for focusing the image onto the chip (62) of the CMOS sensor (61).

Through the lens, the image signal is sent by the chip (62) to a digital processor (DSP) for converting the analog signal into digital signal. The digital signal is provided for a microprocessor for color recovery operation such as zooming, automatic exposure and with balance. The Chip (62) of the CMOS sensor (61) is relatively sensitive to infrared ray and red light. In order to achieve more lively color of the image and avoid bias of the color of the image, a filtering lens (72) is disposed between the focusing lens (71) and the CMOS sensor (61). The filtering lens (72) is formed of a glass piece on which a color filtering layer (73) is deposited. The filtering layer (73) serves to filter and compare royal blue, bright red, yellow, green (auxiliary color filter) and red green, blue (original color filter) light to regulate the shot picture and achieve better image color.

However, the filtering lens (72) will elongate the light path so that the volume of the digital image lens combination cannot be reduced. With reference to FIG. 7, the filtering lens (72) will refract the light beam so that the light beam cannot be projected to an image sensing area (621) of he chip (62) of the CMOS sensor (61). Consequently, it is necessary to increase the distance between the position of the focusing lens (71) and the chip (62) so as to project the light beam onto the image sensing area (621). Accordingly, the length of the digital image lens combination will be elongate. This makes impossible to apply such digital image lens combination to various mini-type digital image instruments.

Furthermore, as shown in FIG. 8, the chip (62) of the CMOS sensor (61) is made of metallic material and the lead frame (622) connecting with the lead of the chip (62) is also metal-made. Consequently, a problem of oxidization exists. Although the CMOS sensor has been packaged, the humidity in the air will still result in oxidization of the chip, lead and lead frame. This will affect the image quality.

The present invention has arisen to mitigate and/or obviate the disadvantages of the conventional digital CMOS sensor.

### SUMMARY OF THE INVENTION

The main objective of the present invention is to provide an improved digital CMOS sensor.

To achieve the objective, the digital CMOS sensor in accordance with the present invention comprises a chip adapted to be electrically connected to a printed circuit board by multiple conducting wires. A transparent layer is fully enveloped the chip and the multiple wires. A convex lens is disposed on a top face of the transparent layer and aligns with the chip for guiding light rays penetrating the transparent layer to the chip.

Further benefits and advantages of the present invention will become apparent after a careful reading of the detailed description with appropriate reference to the accompanying drawings.

### BRIEF DESCRIPTION OF THE DRAWINGS

FIG. 1 is a cross-sectional plan view of a digital CMOS sensor in accordance with the present invention;

FIG. 2 is a cross-sectional plan view of another embodiment of the digital CMOS sensor in accordance with the present invention;

FIG. 3 is a cross-sectional plan view of another embodiment of the digital CMOS sensor in accordance with the present invention;

FIG. 4 is a cross-sectional plan view of another embodiment of the digital CMOS sensor in accordance with the present invention;

FIG. 5 is a cross-sectional plan view of another embodiment of the digital CMOS sensor in accordance with the present invention;

FIG. 6 is a cross-sectional plan view of a digital CMOS sensor in accordance with the prior art;

FIG. 7 shows that the light ray in the conventional digital CMOS sensor is elongated; and

FIG. 8 is a top plan view of a chip of the conventional digital CMOS sensor in FIG. 6.

### DETAILED DESCRIPTION OF THE INVENTION

Referring to the drawings and initially to FIG. 1, a digital CMOS sensor in accordance with the present invention is adapted to be directly secured on a printed circuit board (100) or by a conducting seat (not shown) and comprises a chip (10) electrically connected to the printed circuit board (100) by multiple conducting wires (11) that are made of gold. As well known, the chip (10) is a very thin and small element such that, for easily assembling, a seat (12) is provided to be attached to the printed circuit board (100) and the chip (10) is previously secured on the seat (12) before the digital CMOS sensor being secured on the printed circuit board (100). A transparent layer (20) is fully enveloped the chip (10) the multiple conducting wires (11) and the seat (12) by inject molding. A convex lens (21) extends from a top face of the transparent layer (20) and aligns with the chip (10) for guiding the light rays penetrating the transparent layer (20) to the chip (10). In the preferred embodiment as shown in FIG. 1, the convex lens (21) integrally formed with the transparent layer (20).

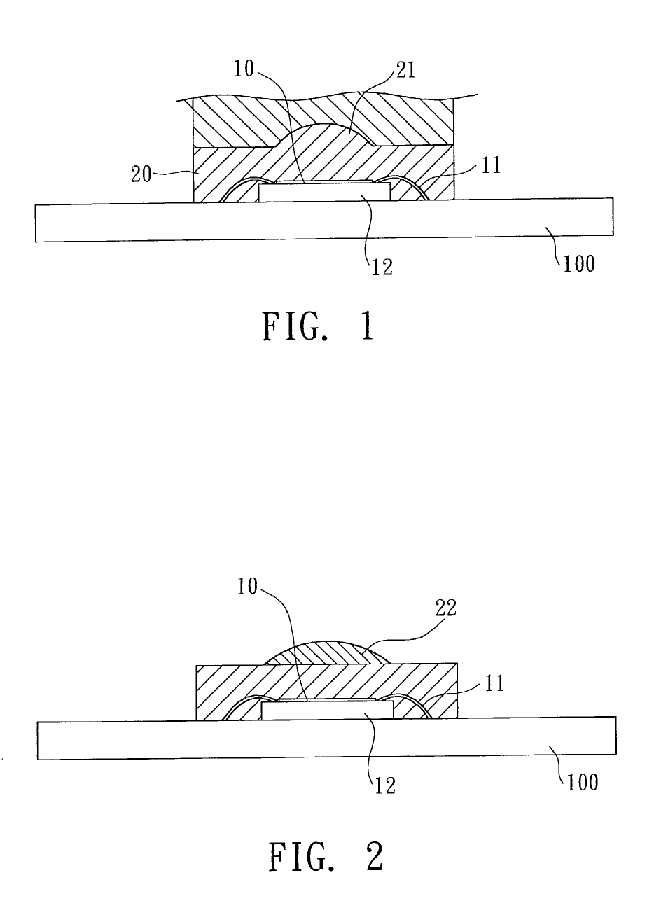

With reference to FIG. 2, it is another embodiment of the present invention, wherein the convex lens (22) is attached to the top face of the transparent layer (20). Consequently, the convex lens (22) can be an achromatic prism for removing achromatic aberrations.

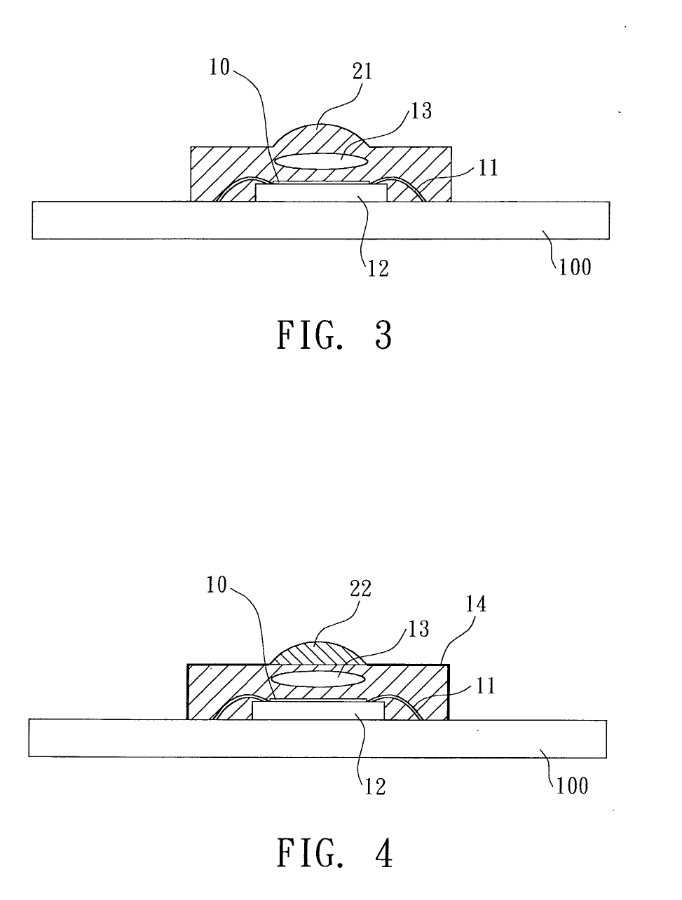

With reference to FIG. 3, the digital CMOS sensor in accordance with the present invention further comprises an achromatic prism (13) is buried in the transparent layer (20) between the chip (10) and the lens (21) for removing achromatic aberrations. The achromatic prism (13) aligns with the chip (10) and the lens (21).

With reference to FIG. 4, the digital CMOS sensor in accordance with the present invention further comprises a shelter (14) covering the transparent layer (20) to segregate the digital CMOS sensor from unnecessary light rays.

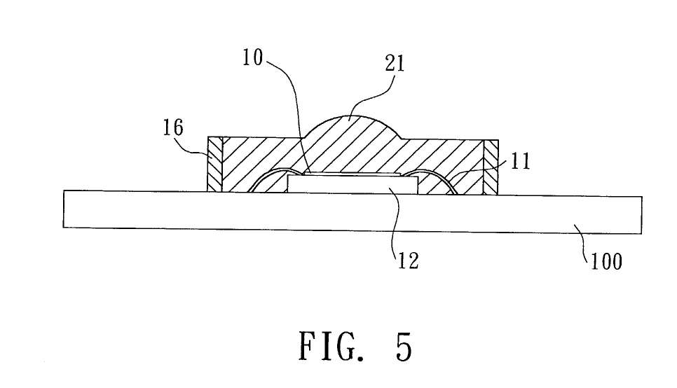

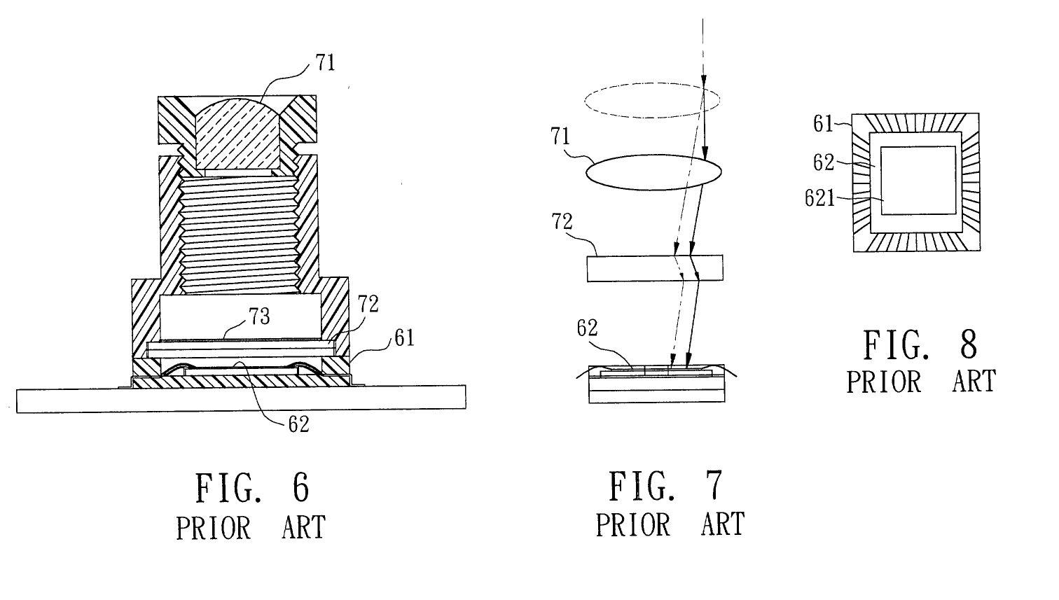

With reference to FIG. 5, the digital CMOS sensor in accordance with the present invention further comprises a frame (16) adapted to be secured on the printed circuit board (100) around the transparent layer (20) to prevent the transparent payer (20) from becoming deformed during molding.

As described above, the convex lens of the present invention can be integrally formed with the transparent layer so that the manufacturing cost is lowered and the volume of the digital CMOS sensor is reduced. Furthermore, the digital CMOS sensor comprises an achromatic prism for removing achromatic aberrations during developing and making the image clearer.

Although the invention has been explained in relation to its preferred embodiment, it is to be understood that many other possible modifications and variations can be made without departing from the spirit and scope of the invention as hereinafter claimed.

What is claimed is:

1. A digital CMOS sensor comprising:
a chip adapted to be electrically connected to a printed circuit board by multiple conducting wires;
a transparent layer fully enveloped the chip and the multiple wires; and
a convex lens disposed on a top face of the transparent layer and aligning with the chip for guiding light rays penetrating the transparent layer to the chip.

2. The digital CMOS sensor as claimed in claim 1, wherein the convex lens is attached to the top face of the transparent layer.

3. The digital CMOS sensor as claimed in claim 1, wherein the convex lens integrally extends from the top face of the transparent layer.

4. The digital CMOS sensor as claimed in claim 2 further comprising an achromatic prism buried in the transparent layer between the lens and the chip for removing achromatic aberrations.

5. The digital CMOS sensor as claimed in claim 3 further comprising an achromatic prism buried in the transparent layer between the lens and the chip for removing achromatic aberrations.

6. The digital CMOS sensor as claimed in claim 4 further comprising a shelter covering the transparent layer to segregate the digital CMOS sensor from unnecessary light rays.

7. The digital CMOS sensor as claimed in claim 4 further comprising a frame mounted around the transparent layer to prevent the transparent layer from becoming deformed during being formed.

8. The digital CMOS sensor as claimed in claim 5 further comprising a shelter covering the transparent layer to segregate the digital CMOS sensor from unnecessary light rays.

9. The digital CMOS sensor as claimed in claim 5 further comprising a frame mounted around the transparent layer to prevent the transparent layer from becoming deformed during being formed.
